(19) United States
(12) Patent Application Publication
(10) Pub. No.: US 2025/0275119 A1
(43) Pub. Date: Aug. 28, 2025

(54) SEMICONDUCTOR MEMORY DEVICE

(71) Applicant: Samsung Electronics Co., Ltd., Suwon-si (KR)

(72) Inventor: Hyungki Cho, Suwon-si (KR)

(21) Appl. No.: 18/903,105

(22) Filed: Oct. 1, 2024

(30) Foreign Application Priority Data
Feb. 28, 2024 (KR) 10-2024-0028551

(51) Int. Cl. H10B 12/00

(52) U.S. Cl. CPC H10B 12/315; H10B 12/05; H10B 12/50

(57) ABSTRACT

A semiconductor memory device may include a first bit line that extends in a first direction, a word line that extends in a second direction intersecting the first direction, a channel pattern between the first bit line and the word line, the channel pattern including a horizontal channel portion, which is electrically connected to the first bit line, and a vertical channel portion, which extends from the horizontal channel portion in a third direction perpendicular to the first and second directions, and a second bit line, which is electrically connected to the first bit line and is in contact with a top surface and at least a portion of a side surface of the horizontal channel portion.

### REFERENCE TO RELATED APPLICATIONS

This U.S. non-provisional patent application claims priority under 35 U.S.C. § 119 to Korean Patent Application No. 10-2024-0028551, filed on Feb. 28, 2024, in the Korean Intellectual Property Office, the entire contents of which are hereby incorporated by reference.

### FIELD OF THE INVENTION

The present disclosure relates to a semiconductor memory device, and in particular, to a semiconductor memory device including vertical channel transistors and a method of fabricating the same.

### BACKGROUND OF THE INVENTION

As a design rule of a semiconductor device decreases, it is possible to increase an integration density and an operation speed of the semiconductor device, but new technologies may be required to improve or maintain a production yield. Thus, a semiconductor device with a vertical channel transistor has been suggested to increase an integration density of a semiconductor device and improve resistance and current driving characteristics of the transistor.

### SUMMARY OF THE INVENTION

An embodiment of the inventive concept provides a semiconductor memory device with improved electrical characteristics.

According to an embodiment of the inventive concept, a semiconductor memory device may include a first bit line that extends in a first direction, a word line that extends in a second direction intersecting the first direction, a channel pattern between the first bit line and the word line, the channel pattern including a horizontal channel portion, which is electrically connected to the first bit line, and a vertical channel portion, which extends from the horizontal channel portion in a third direction perpendicular to the first and second directions, and a second bit line, which is electrically connected to the first bit line and is in contact with a top surface and at least a portion of a side surface of the horizontal channel portion.

According to an embodiment of the inventive concept, a semiconductor memory device may include a bit line that extends in a first direction, a word line that extends in a second direction intersecting the first direction, and a channel pattern between the bit line and the word line, the channel pattern including a horizontal channel portion electrically connected to the bit line and a vertical channel portion, which protrudes from the horizontal channel portion in a third direction perpendicular to the first and second directions. The bit line may include a first bit line on the channel pattern opposite the word line and in contact with a bottom surface of the horizontal channel portion, and a second bit line electrically connected to the first bit line and between the word line and the horizontal channel portion.

According to an embodiment of the inventive concept, a semiconductor memory device may include a peripheral circuit structure including peripheral circuits on a semiconductor substrate and a lower insulating layer on the peripheral circuits, first bit lines on the peripheral circuit structure and extending in a first direction, mold insulating patterns extending in a second direction to cross the first bit lines, word lines between the mold insulating patterns and extending in the second direction to cross the first bit lines, channel patterns between the first bit lines and the word lines, each of the channel patterns including a horizontal channel portion, which is electrically connected to the first bit line, and first and second vertical channel portions, which extend from opposite end portions of the horizontal channel portion in a third direction perpendicular to the first and second directions, second bit lines electrically connected to the first bit lines, the second bit lines being between the word lines and the horizontal channel portion of the channel patterns, a gate insulating pattern between the channel patterns and the word lines and between the second bit line and the word lines, landing pads electrically connected to the first and second vertical channel portions of the channel patterns, respectively, and data storage patterns on the landing pads, respectively.

### BRIEF DESCRIPTION OF THE DRAWINGS

FIG. 1 is a block diagram illustrating a semiconductor memory device including a semiconductor device according to an embodiment of the inventive concept.

FIG. 2 is a perspective view schematically illustrating a semiconductor memory device according to an embodiment of the inventive concept.

FIG. 3A is a plan view illustrating a semiconductor memory device according to an embodiment of the inventive concept.

FIGS. 3B and 3C are section views, which are taken along lines A-A′, B-B′, C-C′, and D-D′ of FIG. 3A to illustrate a semiconductor memory device according to an embodiment of the inventive concept.

FIGS. 4A and 4B are enlarged views illustrating a portion ‘P1’ of FIG. 3B and a portion ‘P2’ of FIG. 3C, respectively.

FIGS. 5A, 5B, 5C, 6A, 6B, 6C, 7A, 7B, 7C, 8A, 8B, 8C, 9, 10, 11A, 11B, 11C, 12A, 12B, and 12C are diagrams illustrating a method of fabricating a semiconductor memory device, according to an embodiment of the inventive concept.

### DETAILED DESCRIPTION

Example embodiments of the inventive concepts will now be described more fully with reference to the accompanying drawings, in which example embodiments are shown. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

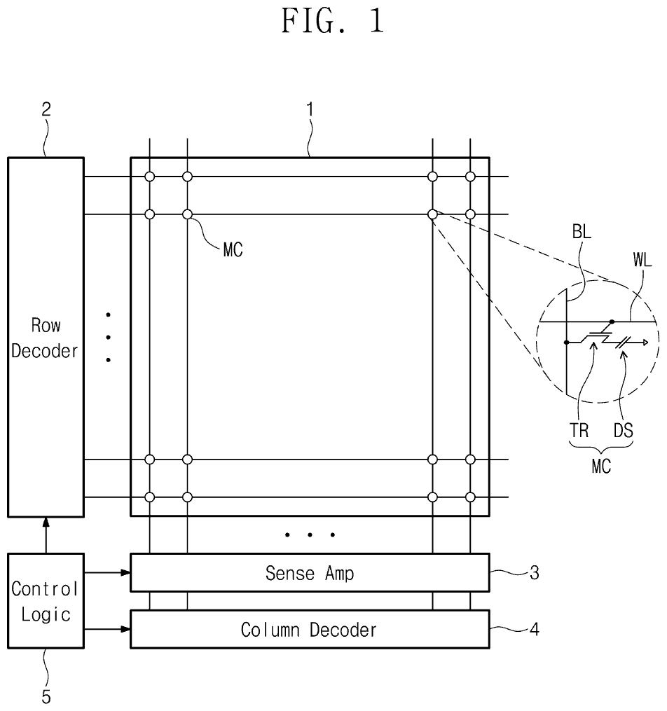

FIG. 1 is a block diagram illustrating a semiconductor memory device including a semiconductor device according to an embodiment of the inventive concept.

Referring to FIG. 1, the semiconductor memory device may include a memory cell array 1, a row decoder 2, a sense amplifier 3, a column decoder 4, and a control logic 5.

The memory cell array 1 may include a plurality of memory cells MC, which are two- or three-dimensionally arranged. Each of the memory cells MC may be disposed between and connected to a word line WL and a bit line BL, which are disposed to cross each other.

Each of the memory cells MC may include a selection element TR and a data storage element DS, which are electrically connected to each other in series. The selection element TR may be disposed between and connected to the data storage element DS and the word line WL, and the data storage element DS may be connected to the bit line BL through the selection element TR. The selection element TR may be a field effect transistor (FET), and the data storage element DS may be realized using at least one of a capacitor, a magnetic tunnel junction pattern, or a variable resistor. As an example, the selection element TR may include a transistor whose gate electrode is connected to the word line WL and whose drain/source terminals are connected to the bit line BL and the data storage element DS, respectively.

The row decoder 2 may be configured to decode address information, which is input from the outside (e.g., from an external device), and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

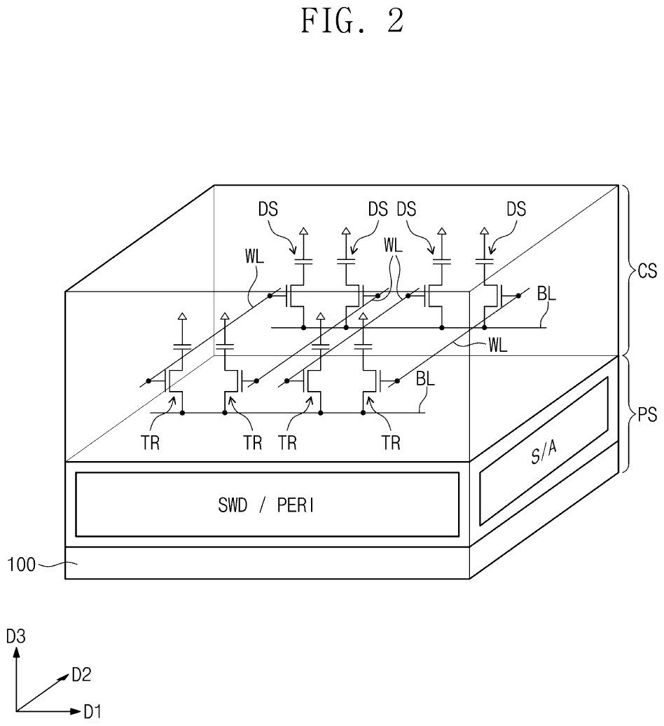

FIG. 2 is a perspective view schematically illustrating a semiconductor memory device according to an embodiment of the inventive concept.

Referring to FIG. 2, the semiconductor memory device may include a peripheral circuit structure PS on a semiconductor substrate 100 and a cell array structure CS on the peripheral circuit structure PS.

The peripheral circuit structure PS may include the peripheral circuit structure PS on the semiconductor substrate 100 and the cell array structure CS on the peripheral circuit structure PS. In other words, the peripheral circuit structure PS may be placed or provided between the semiconductor substrate 100 and the cell array structure CS in a third direction D3 that is perpendicular to a top surface of the semiconductor substrate 100.

The peripheral circuit structure PS may include core and peripheral circuits formed on the semiconductor substrate 100. The core and peripheral circuits may include the row decoder 2, the column decoder 4, the sense amplifier 3, and the control logic 5 described with reference to FIG. 1.

The cell array structure CS may include the bit lines BL, the word lines WL, and the memory cells MC (e.g., of FIG. 1) between the bit lines BL and the word lines WL. The memory cells MC of FIG. 1 may be two-or three-dimensionally arranged on a plane that are parallel to two different directions (e.g., a first direction D1 and a second direction D2). Each of the memory cells MC of FIG. 1 may include the selection element TR and the data storage element DS.

The selection element TR may include, for example, a vertical channel transistor (VCT). A channel region of the vertical channel transistor may have a shape that is extended in a vertical direction (e.g., the third direction D3) perpendicular to the top surface of the semiconductor substrate 100. The data storage element DS may include a capacitor. However, the inventive concept is not limited to this example. In an embodiment, the semiconductor memory device may include the cell array structure CS on the semiconductor substrate 100 and the peripheral circuit structure PS on the cell array structure CS. In other words, the cell array structure CS may be provided between the semiconductor substrate 100 and the peripheral circuit structure PS. Alternatively, the semiconductor memory device may be provided to have a chip-to-chip (C2C) structure. In the present specification, the C2C structure may mean a structure that is formed by bonding an upper chip including the cell array structure CS to a lower chip including the peripheral circuit structure PS. In an embodiment, the upper and lower chips may be bonded to each other through a hybrid bonding process. Here, the hybrid bonding process may mean a bonding process of fusing two elements, which contain the same kind of material, into a single element at an interface therebetween.

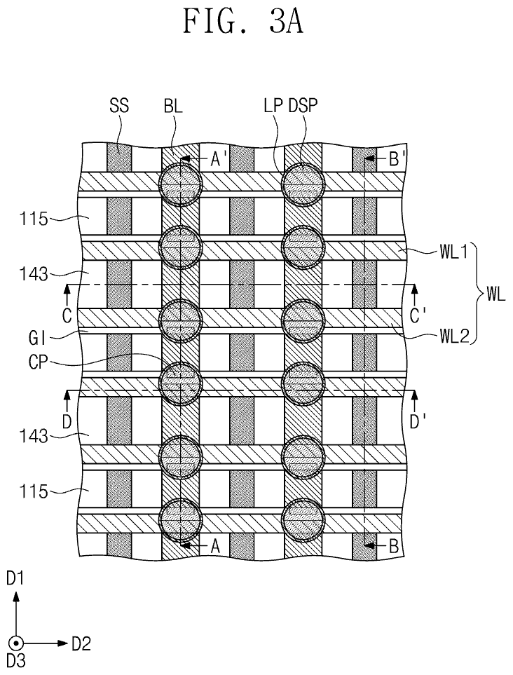

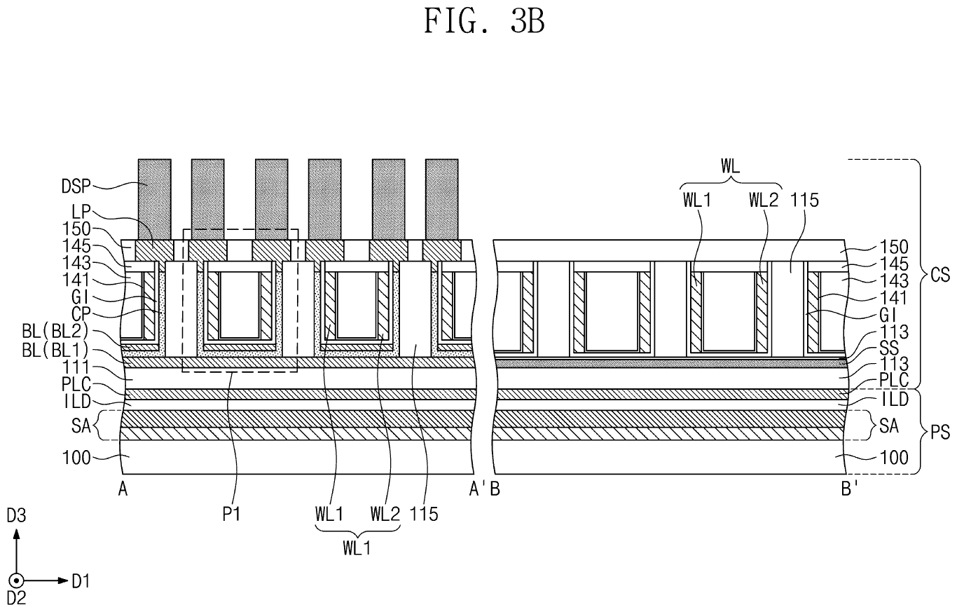

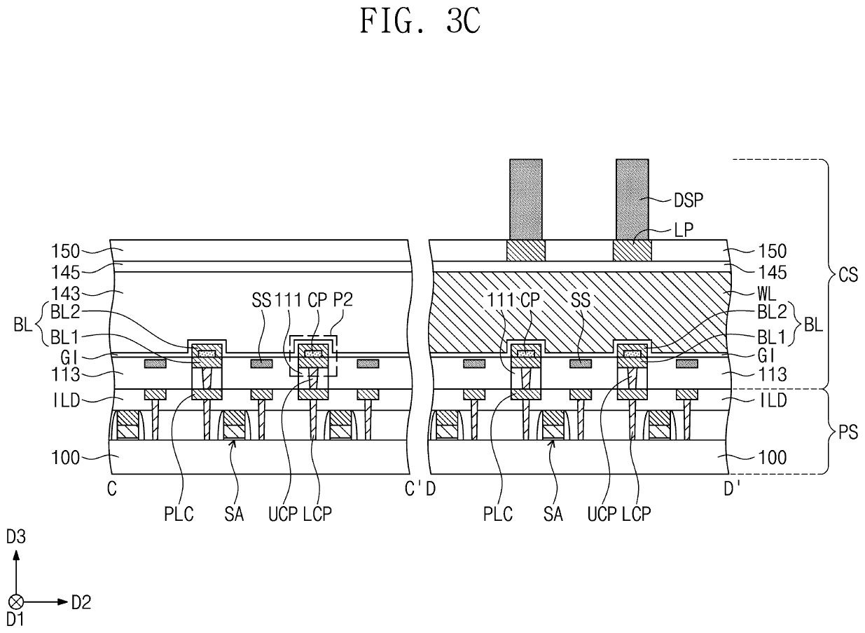

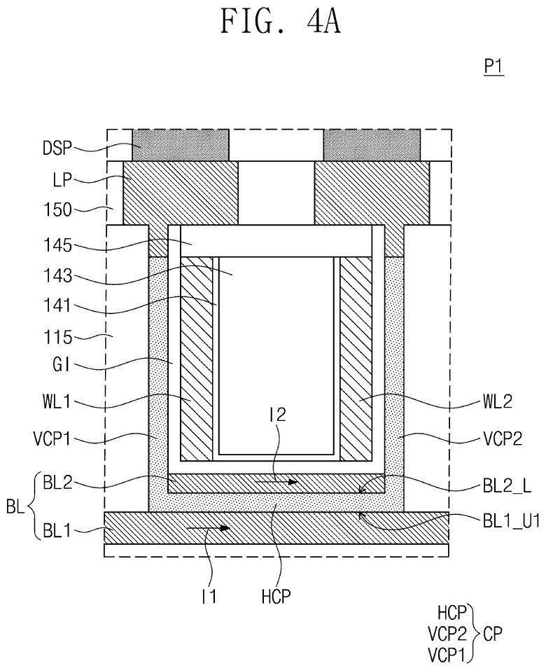

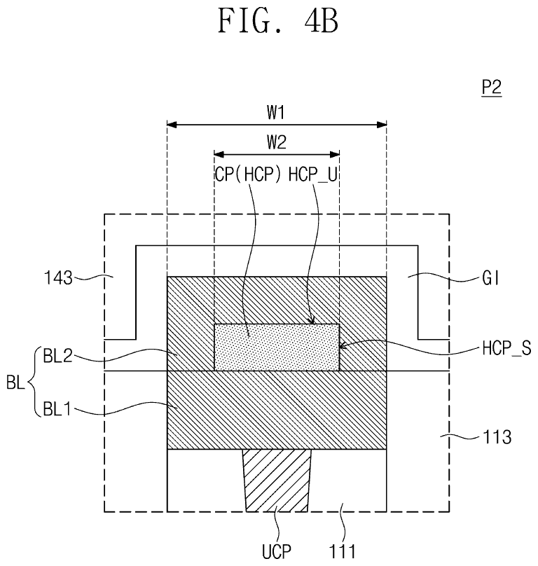

FIG. 3A is a plan view illustrating a semiconductor memory device according to an embodiment of the inventive concept. FIGS. 3B and 3C are section views, which are taken along lines A-A′, B-B′, C-C′, and D-D′ of FIG. 3A to illustrate a semiconductor memory device according to an embodiment of the inventive concept. FIGS. 4A and 4B are enlarged views illustrating a portion ‘P1’ of FIG. 3B and a portion ‘P2’ of FIG. 3C, respectively.

Referring to FIGS. 3A, 3B, and 3C, the semiconductor memory device according to an embodiment of the inventive concept may include the peripheral circuit structure PS and the cell array structure CS on the peripheral circuit structure PS.

The peripheral circuit structure PS may include core circuits SA integrated on the semiconductor substrate 100, a lower insulating layer ILD covering the core circuits SA, lower contact plugs LCP, and circuit interconnection lines PLC. The term “covering” or “enclosing” or “surrounding” as may be used herein may not require completely covering or enclosing or surrounding the described elements or layers, but may, for example, refer to partially covering or enclosing or surrounding the described elements or layers, for example, with discontinuities or other spaces throughout.

In an embodiment, the semiconductor substrate 100 may be a single-crystalline silicon substrate. The top surface of the semiconductor substrate 100 may be parallel to the first and second directions D1 and D2. The top surface of the semiconductor substrate 100 may be orthogonal to the third direction D3.

The core circuits SA may include NMOS and PMOS transistors, which are integrated on the semiconductor substrate 100. The core circuits SA may be electrically connected to the bit lines BL and the word lines WL through the circuit interconnection lines PLC.

The lower insulating layer ILD may be provided on the semiconductor substrate 100 to cover the core circuits SA, the circuit interconnection lines PLC, and the lower contact plugs LCP. The lower contact plugs LCP may electrically connect the core circuits SA to the circuit interconnection lines PLC. The lower insulating layer ILD may have a substantially flat top surface. For example, the lower insulating layer ILD may be formed of or include at least one of silicon oxide, silicon nitride, silicon oxynitride, and/or low-k dielectric materials. Alternatively, the lower insulating layer ILD may have a multi-layered structure including two or more different materials.

The cell array structure CS may be located on the lower insulating layer ILD. The cell array structure CS may include bit lines BL, channel patterns CP, first and second word lines WL1 and WL2, a gate insulating layer GI, landing pads LP, and data storage patterns DSP.

A first interlayer insulating pattern 111 may be provided on the lower insulating layer ILD. The first interlayer insulating pattern 111 may cover a portion of the lower insulating layer ILD. The first interlayer insulating pattern 111 may be provided between first bit lines BL1 and the circuit interconnection lines PLC. The first interlayer insulating pattern 111 may be provided to enclose upper contact plugs UCP, which are formed to connect the first bit lines BL1 to the circuit interconnection lines PLC.

A second interlayer insulating pattern 113 may be provided on the lower insulating layer ILD. The second interlayer insulating pattern 113 may cover the first interlayer insulating pattern 111. A portion of the second interlayer insulating pattern 113 may fill a space between the first bit lines BL1. In an embodiment, the first and second interlayer insulating patterns 111 and 113 may be formed of or include at least one of silicon oxide, silicon nitride, silicon oxynitride, and/or low-k dielectric materials.

The bit lines BL on the lower insulating layer ILD may extend in the first direction D1 and may be spaced apart from each other in the second direction D2. Each of the bit lines BL may include the first bit line BL1 and a second bit line BL2, which are connected to each other vertically (e.g., in the third direction D3). Each of the first bit lines BL1 may be disposed on the lower insulating layer ILD and may be coplanar with the second interlayer insulating pattern 113. The second bit lines BL2 may be formed on the second interlayer insulating pattern 113 and the first bit lines BL1. In an embodiment, the second bit lines BL2 may be spaced apart from each other in the first direction D1, and the second bit lines BL2, which are spaced apart from each other in the first direction D1, may be provided on and connected to the first bit line BL1, respectively. The channel pattern CP may be disposed between the first and second bit lines BL1 and BL2, which are connected to each other. In an embodiment, the first and second bit lines BL1 and BL2 may include doped polysilicon, metallic materials, conductive metal nitride materials, conductive metal silicide materials, conductive metal oxide materials, or combinations thereof. Each of the first and second bit lines BL1 and BL2 may be provided to form a single-or multi-layered structure. In an embodiment, the first and second bit lines BL1 and BL2 may be formed of or include at least one of carbon-based two-dimensional materials (e.g., graphene) or carbon-based three-dimensional materials (e.g., carbon nanotube).

Shielding structures SS may be provided in the second interlayer insulating pattern 113. Each of the shielding structures SS may be provided between adjacent ones of the first bit lines BL1. The shielding structures SS may extend in the first direction D1 and may be spaced apart from each other in the second direction D2. Top surfaces of the shielding structures SS may be provided at a level or height that is lower than top surfaces of the first bit lines BL1. The shielding structures SS may be formed of or include at least one of a conductive material (e.g., a metallic material), and in an embodiment, an air gap or void may be formed in the conductive material.

Mold insulating patterns 115 may be provided on the second interlayer insulating pattern 113 and the first bit lines BL1. Each of the mold insulating patterns 115 may extend in the second direction D2 to cross the first bit lines BL1. For example, the mold insulating patterns 115 may be formed of or include at least one of silicon oxide, silicon nitride, silicon oxynitride, and/or low-k dielectric materials.

The channel patterns CP may be disposed on the first bit lines BL1. The channel patterns CP on each of the first bit lines BL1 may be spaced apart from each other in the first direction D1 by the mold insulating patterns 115, and each of the channel patterns CP may have a ‘U’-shaped section.

The first and second word lines WL1 and WL2 may be provided on the channel patterns CP. The first and second word lines WL1 and WL2 may extend in the second direction D2 to cross the bit lines BL and the channel patterns CP. The first and second word lines WL1 and WL2 may be alternately arranged in the first direction D1. For example, a pair of the first and second word lines WL1 and WL2 may be provided to correspond to each of the channel patterns CP.

For example, the first and second word lines WL1 and WL2 may include doped polysilicon, metallic materials, conductive metal nitride materials, conductive metal silicide materials, conductive metal oxide materials, or combinations thereof. The first and second word lines WL1 and WL2 may have a single layer or may have a multi-layered structure including two or more different materials. In an embodiment, the first and second word lines WL1 and WL2 may be formed of or include at least one of carbon-based two-dimensional materials (e.g., graphene) or carbon-based three-dimensional materials (e.g., carbon nanotube).

In more detail, referring to FIGS. 3B, 3C, 4A, and 4B, the channel pattern CP may include a horizontal channel portion HCP and vertical channel portions VCP1 and VCP2, which are connected to opposite end portions of the horizontal channel portion HCP. The horizontal channel portion HCP may have a shape, which is extended in the first direction D1, on the bit line BL. The horizontal channel portion HCP may be in contact with a top surface of the first bit line BL1. The vertical channel portions VCP1 and VCP2 may include a first vertical channel portion VCP1 and a second vertical channel portion VCP2. In the present specification, the vertical channel portion VCP1 or VCP2 may be one of the first and second vertical channel portions VCP1 and VCP2. Each of the first and second vertical channel portions VCP1 and VCP2 may have a shape that is extended from an end portion of the horizontal channel portion HCP in the third direction D3. The first and second vertical channel portions VCP1 and VCP2 may be spaced apart from each other in the first direction D1. The channel pattern CP may have a uniform thickness. In other words, a thickness of the horizontal channel portion HCP in the third direction D3 may be substantially equal to a thickness of each of the first and second vertical channel portions VCP1 and VCP2 in the first direction D1.

In an embodiment, the channel patterns CP may include an oxide semiconductor material. The oxide semiconductor material may be formed of or include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. Alternatively, the channel patterns CP may be formed of or include indium gallium zinc oxide (IGZO). Each of the channel patterns CP may have a single-layered structure, which contains an oxide semiconductor material, or a multi-layered structure, which contains at least two different oxide semiconductor materials. In addition, the channel patterns CP may be formed of or include an amorphous, single-crystalline, or poly-crystalline oxide semiconductor material. For example, the channel patterns CP may have a band gap energy that is greater than that of silicon. In detail, the channel patterns CP may have a band gap energy of about 1.5 eV to about 5.6 eV, and in the case where the channel patterns CP has a band gap energy of about 2.0 eV to about 4.0 eV, the channel performance may be optimized.

A width W2 of the horizontal channel portion HCP in the second direction D2 may be smaller than a width of the first bit line BL1 in the second direction D2. The second bit line BL2 may be in contact with a top surface HCP_U and at least a portion of a side surface HCP_S of the horizontal channel portion HCP and may be connected to the top surface of the first bit line BL1. For example, a portion of the horizontal channel portion HCP may be enclosed by the first and second bit lines BL1 and BL2.

On the horizontal channel portion HCP, the second bit line BL2 may be in contact with side surfaces of the vertical channel portions VCP1 and VCP2. For example, an end portion of the second bit line BL2 may be in contact with the side surface of the first vertical channel portion VCP1, and an opposite end portion of the second bit line BL2 may be in contact with the side surface of the second vertical channel portion VCP2. The first bit line BL1 may be in contact with a bottom surface of the horizontal channel portion HCP, below the channel pattern CP.

As will be described later, when the horizontal channel portion HCP is formed on the first bit line BL1, a portion of the first bit line BL1 (hereinafter, a first portion BL1_U1) may be oxidized. Thus, the first portion BL1_U1 of the first bit line BL1, which is in contact with the horizontal channel portion HCP, may include a conductive metal oxide material and may have a large electric resistance. By contrast, the second bit line BL2, which is formed on the horizontal channel portion HCP, may be less or barely oxidized, compared with the first bit line BL1, and thus, the second bit line BL2 may have an electrical resistance that is lower than the first portion BL1_U1 of the first bit line BL1.

In other words, according to an embodiment of the inventive concept, the second bit line BL2, which has an higher electrical conductivity than that of the first portion BL1_U1 of the first bit line BL1, may be provided on the horizontal channel portion HCP and may be connected to the first bit line BL1. As a result, most of a current may flow through the second bit line BL2, which is connected to the first bit line BL1, rather than through the first portion BL1_U1 of the first bit line BL1 having a relatively high electric resistance. A magnitude of a current I2 passing through the second bit line BL2 may be greater than a magnitude of a current I1 passing through the first portion BL1_U1 of the first bit line BL1. In an embodiment, the magnitude of the current I2 passing through the second bit line BL2 may be 10 to 1000 times the magnitude of the current I1 passing through the first portion BLI_U1 of the first bit line BL1.

In addition, according to an embodiment of the inventive concept, the second bit line BL2 may be disposed between the word lines WL1 and WL2 and the channel pattern CP. Thus, distances between the word lines WL1 and WL2 and the channel pattern CP may be increased, and a strength of an electric field, which may be produced between the word lines WL1 and WL2 and the channel pattern CP, may be reduced. Accordingly, charge traps (e.g., donor traps or acceptor traps), which are formed in the horizontal channel portion HCP in contact with the first bit line BL1, may be less moved or less likely to migrate to a vertical channel portion VCP serving as an effective channel. Thus, the electrical reliability of the semiconductor memory device may be improved.

The first word line WL1 and the second word line WL2 may be provided on the horizontal channel portion HCP of the channel pattern CP and on the second bit line BL2. The first word line WL1 may be provided adjacent to the first vertical channel portion VCP1 and may extend in the third direction D3. The second word line WL2 may be provided adjacent to the second vertical channel portion VCP2 and may extend in the third direction D3. For example, the first word line WL1 on the horizontal channel portion HCP may extend along an inner side surface of the first vertical channel portion VCP1, and the second word line WL2 on the horizontal channel portion HCP may extend along an inner side surface of the second vertical channel portion VCP2. The first and second word lines WL1 and WL2 may have substantially the same thickness in the first direction D1.

The gate insulating layer GI may be provided between the channel pattern CP and the first and second word lines WL1 and WL2 and between the second bit line BL2 and the first and second word lines WL1 and WL2 and may have a uniform thickness. The gate insulating layer GI may be in contact with the channel pattern CP, the first and second word lines WL1 and WL2, and a top surface of the second bit line BL2. The gate insulating layer GI may extend from the horizontal channel portion HCP of the channel pattern CP to a region between the first vertical channel portion VCP1 and the first word line WL1 and between the second vertical channel portion VCP2 and the second word line WL2.

The gate insulating layer GI may be formed of silicon oxide, silicon oxynitride, a high-k dielectric material having a higher dielectric constant than silicon oxide, or combinations thereof. The high-k dielectric material may include HfO₂, HfSiO, HfSiON, HfTaO, HfTiO, HfZrO, ZrO₂, Al₂O₃, or combinations thereof, but the inventive concept is not limited to this example.

Referring back to FIGS. 3A, 3B, and 3C, first insulating patterns 143 may be provided between the first and second word lines WL1 and WL2. Each of the first insulating patterns 143 may be provided between a corresponding pair of the first and second word lines WL1 and WL2. Each of the first insulating patterns 143 may extend in the second direction D2. The first insulating patterns 143 may be spaced apart from each other in the first direction D1. The first insulating patterns 143 and the mold insulating patterns 115 may be alternately arranged in the first direction D1.

A first capping pattern 141 may be disposed between outer side surfaces of the first and second word lines WL1 and WL2 and the first insulating pattern 143 and between the gate insulating layer GI and the first insulating pattern 143. The first capping pattern 141 may have a substantially uniform thickness.

Second capping patterns 145 may be provided on the first and second word lines WL1 and WL2. The second capping patterns 145 may cover top surfaces of the first insulating patterns 143. Each of the second capping patterns 145 may extend in the second direction D2. Top surfaces of the second capping patterns 145 may be substantially coplanar with top surfaces of the mold insulating patterns 115.

The first and second capping patterns 141 and 145 may be formed of an insulating material different from the first insulating patterns 143. For example, the first insulating patterns 143 may be formed of or include silicon oxide, and the first and second capping patterns 141 and 145 may be formed of or include silicon nitride.

The landing pads LP may be disposed on the first and second vertical channel portions VCP1 and VCP2 of the channel pattern CP. The landing pads LP may be in direct contact with the first and second vertical channel portions VCP1 and VCP2. The landing pads LP may have various shapes (e.g., circular, elliptical, rectangular, square, diamond, and hexagonal shapes), when viewed in a plan view. The landing pads LP may be spaced apart from each other in the first and second directions D1 and D2, as shown in FIG. 3A.

The landing pads LP may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to this example.

The data storage patterns DSP may be located on the landing pads LP. The data storage patterns DSP may be electrically connected to the channel patterns CP through the landing pads LP. When viewed in a plan view, each of the data storage patterns DSP may be overlapped with a corresponding one of the landing pads LP. In other words, the data storage patterns DSP may be spaced apart from each other in the first and second directions D1 and D2.

For example, the data storage pattern DSP may be a capacitor. In this case, the data storage pattern DSP may include a bottom electrode, a top electrode, and a dielectric layer therebetween. The bottom electrode may be in contact with the landing pad LP. Alternatively, the data storage patterns DSP may be a variable resistance pattern whose resistance can be switched to one of at least two states by an electric pulse applied thereto. For example, the data storage patterns DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

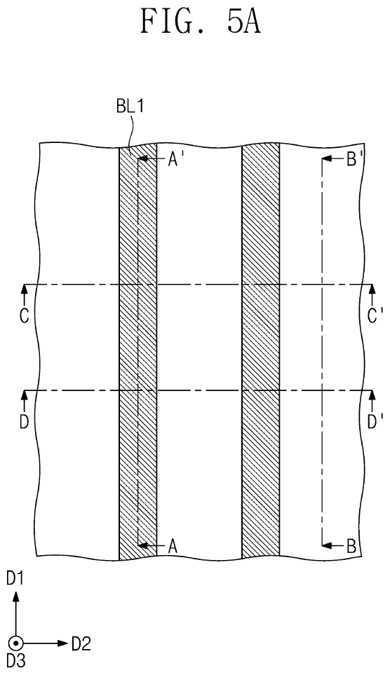

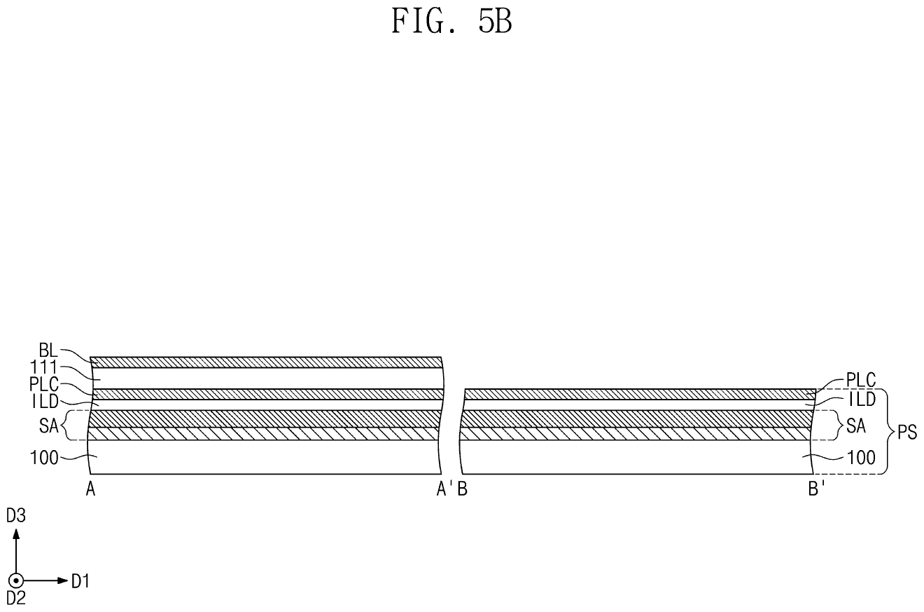

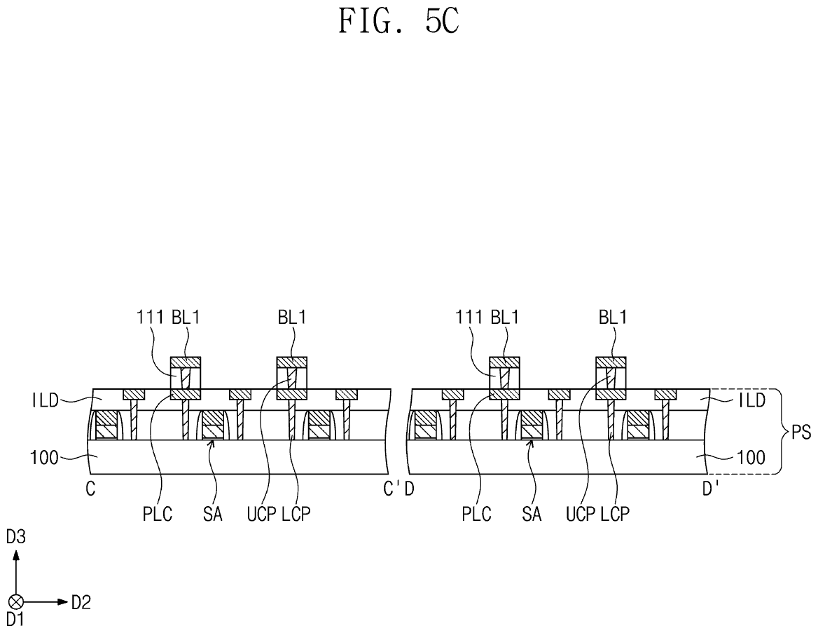

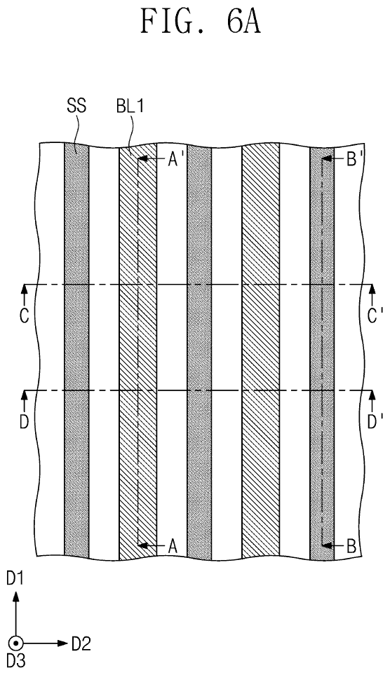

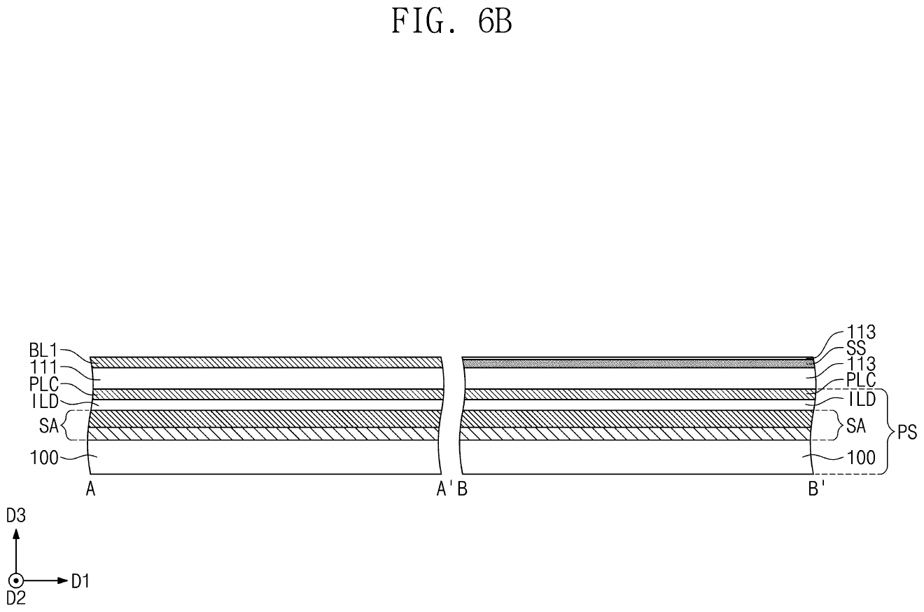

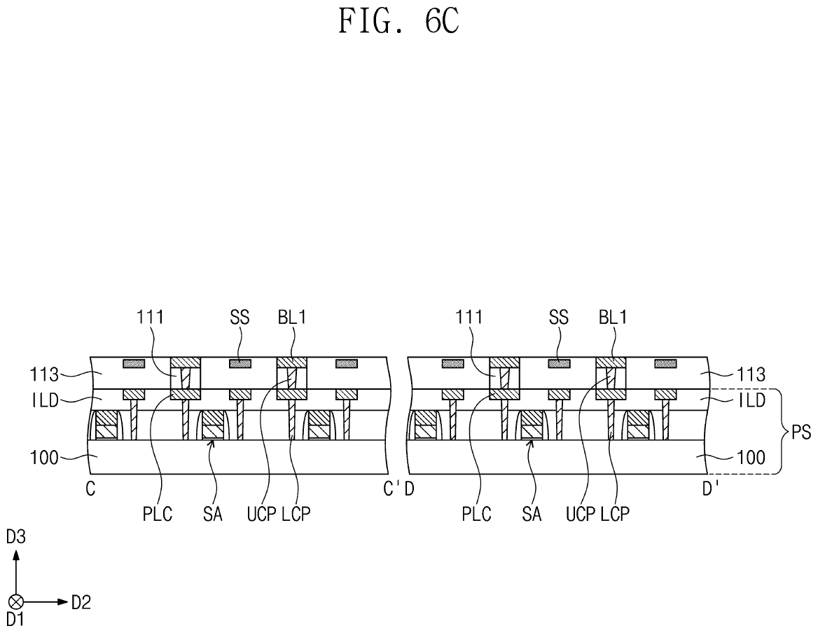

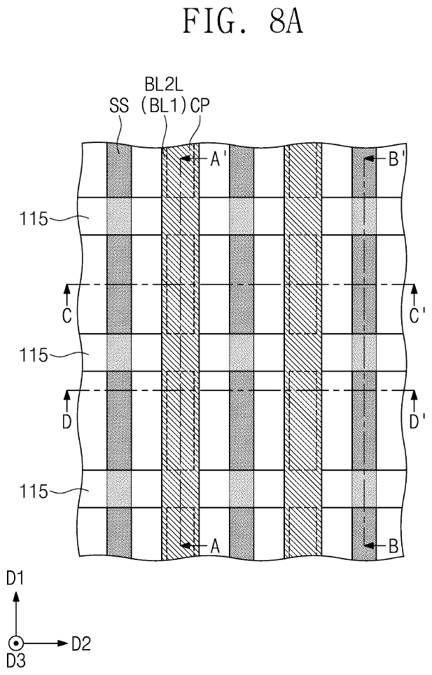

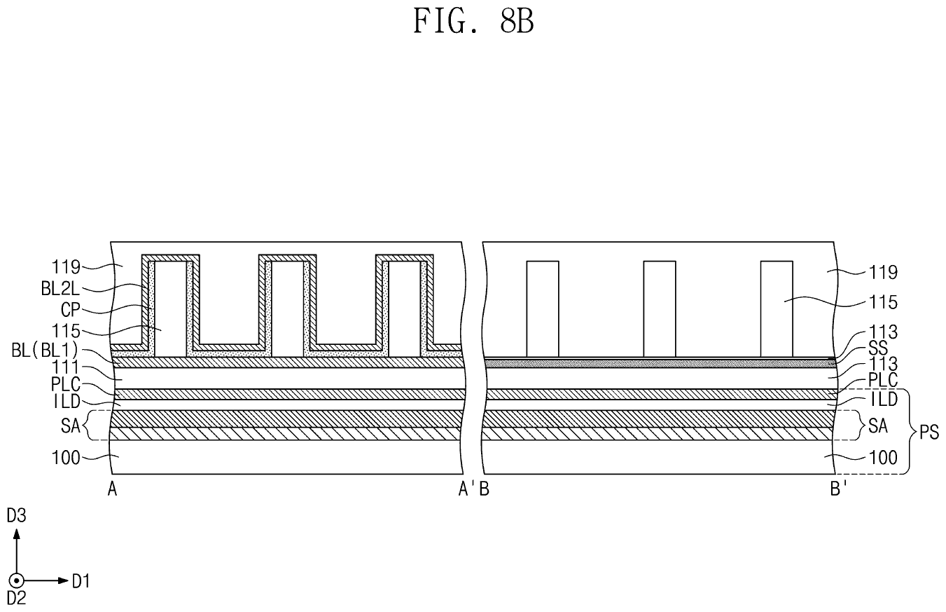

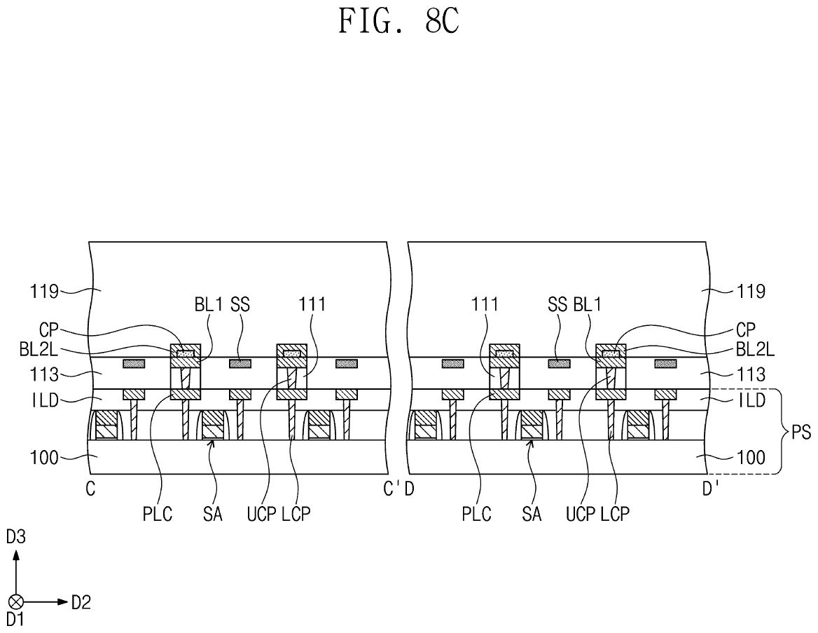

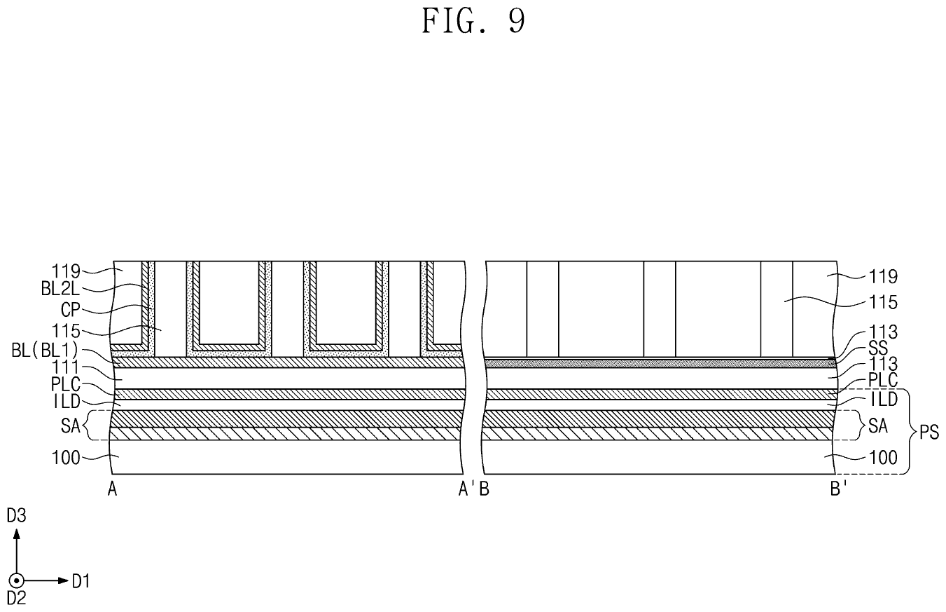

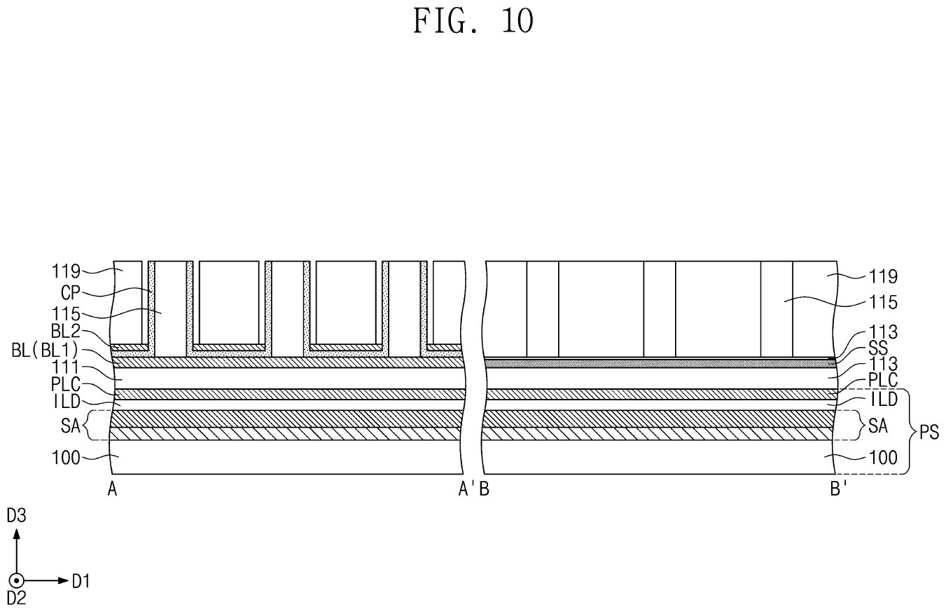

FIGS. 5A to 12C are diagrams illustrating a method of fabricating a semiconductor memory device, according to an embodiment of the inventive concept. In more detail, FIGS. 5A, 6A, 7A, 8A, 11A, and 11A are plan views of the semiconductor memory device, FIGS. 6B, 7B, 8B, 11B, and 12B are sectional views taken along lines A-A′ and B-B′ of FIGS. 5A, 6A, 7A, 8A, 11A, and 12A, respectively, and FIGS. 6C, 7C, 8C, 11C, and 12C are sectional views taken along lines C-C′ and D-D′ of FIGS. 5A, 6A, 7A, 8A, 11A, and 12A, respectively. FIGS. 9 and 10 are sectional views taken along lines A-A′ and B-B′ of FIG. 8B.

Referring to FIGS. 5A, 5B, and 5C, the peripheral circuit structure PS including the core circuits SA may be formed on the semiconductor substrate 100.

In detail, the core circuits SA may be formed on the semiconductor substrate 100, and the lower insulating layer ILD may be formed to cover the core circuits SA. For example, the lower insulating layer ILD may be formed of or include at least one of silicon oxide, silicon nitride, silicon oxynitride, and/or low-k dielectric materials and may have a single layer or may have a multi-layered structure including two or more different materials.

In an embodiment, the circuit interconnection lines PLC and the lower contact plugs LCP, which are connected to each other, may be formed in the lower insulating layer ILD. The circuit interconnection lines PLC may be electrically connected to the core circuits SA through the lower contact plugs LCP.

The first bit lines BL1 may be formed on the lower insulating layer ILD. The formation of the first bit lines BL1 may include forming a first interlayer insulating layer on the lower insulating layer ILD, forming the upper contact plugs UCP to penetrate the first interlayer insulating layer, depositing a lower conductive layer on the first interlayer insulating layer, and patterning the lower conductive layer and the first interlayer insulating layer. Thus, the first bit lines BL1 and the first interlayer insulating pattern 111 may be formed from the lower conductive layer and the first interlayer insulating layer. Furthermore, the lower insulating layer ILD may be partially exposed to the outside. The term “exposed,” may be used to describe relationships between elements and/or certain intermediate processes in fabricating a completed semiconductor device, but may not necessarily require exposure of the particular region, layer, structure or other element in the context of the completed device.

Referring to FIGS. 6A, 6B, and 6C, a second interlayer insulating layer may be formed on the lower insulating layer ILD to cover the top surface of the lower insulating layer ILD and the first bit lines BL1 with a uniform thickness. The shielding structures SS may be formed on the second interlayer insulating layer. The formation of the shielding structures SS may include forming a shielding layer on the second interlayer insulating layer and recessing a top surface of the shielding layer. In an embodiment, the shielding layer and the shielding structures SS may be formed of or include a metallic material (e.g., W, Ti, Ni, and Co) or a conductive two-dimensional (2D) material (e.g., graphene). Next, an insulating material may be deposited on the second interlayer insulating layer and the shielding structures SS, and a planarization process may be performed on the insulating material and the second interlayer insulating layer to form the second interlayer insulating pattern 113. In an embodiment, the planarization process may be performed to expose top surfaces of the first bit lines BL1, but top surfaces of the shielding structures SS may not be exposed to the outside.

In the present specification, an example, in which the semiconductor memory device includes the shielding structures SS, is illustrated, but the inventive concept is not limited to this example. For example, the formation of the shielding structures SS may be omitted, and in this case, a space between the first bit lines BL1, which are adjacent to each other may be filled with the second interlayer insulating pattern 113.

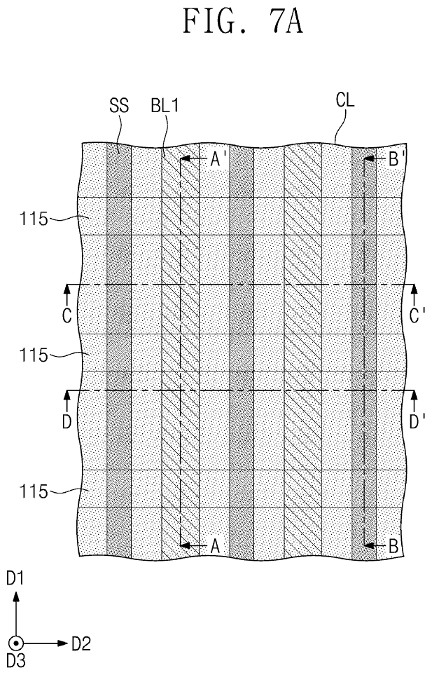

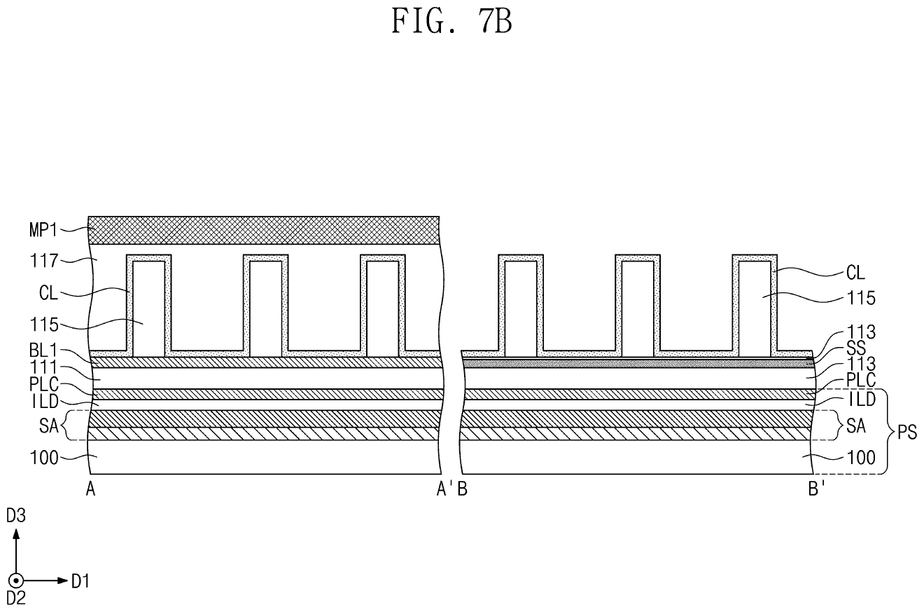

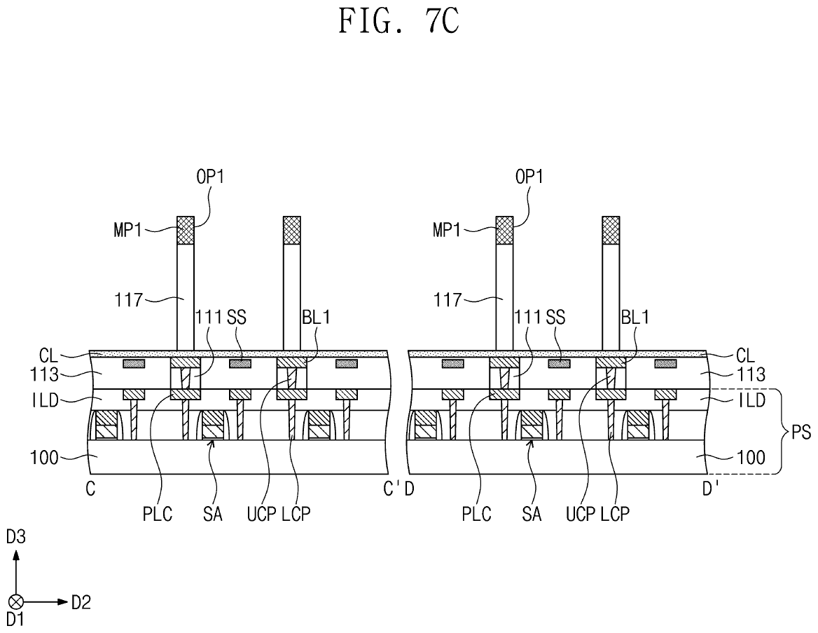

Referring to FIGS. 7A, 7B, and 7C, the mold insulating patterns 115 may be formed on the second interlayer insulating pattern 113 and the first bit lines BL1. The mold insulating patterns 115 may extend in the second direction D2 and may be spaced apart from each other in the first direction D1. The mold insulating patterns 115 may be formed to expose portions of the first bit lines BL1.

The mold insulating patterns 115 may include a material having an etch selectivity with respect to the second interlayer insulating pattern 113. For example, the mold insulating patterns 115 may be formed of or include at least one of silicon oxide, silicon nitride, silicon oxynitride, and/or low-k dielectric materials.

A channel layer CL may be formed to cover the mold insulating patterns 115. The channel layer CL may be formed to have a uniform thickness. The channel layer CL may cover the bit lines BL and the second interlayer insulating pattern 113, and the mold insulating patterns 115. The channel layer CL may be formed using at least one of physical vapor deposition (PVD), thermal chemical vapor deposition (thermal CVD), low-pressure chemical vapor deposition (LP-CVD), plasma enhanced chemical vapor deposition (PE-CVD), or atomic layer deposition (ALD) technologies. The channel layer CL may be formed of or include at least one of semiconductor materials, oxide semiconductor materials, or two-dimensional semiconductor materials and may be formed of or include at least one of, for example, silicon, germanium, silicon-germanium, or indium gallium zinc oxide (IGZO).

A first sacrificial layer 117 may be formed on the channel layer CL. The first sacrificial layer 117 may have a substantially flat top surface. The first sacrificial layer 117 may include a material having an etch selectivity with respect to the mold insulating patterns 115. For example, the first sacrificial layer 117 may be formed of or include at least one of insulating materials, which are formed using a spin-on-glass (SOG) method, or silicon oxide.

First mask patterns MP1 may be formed on the first sacrificial layer 117. The first mask patterns MP1 may be formed to have first openings OP1. The first sacrificial layer 117 may be spaced apart from each other in the second direction D2, and the first mask patterns MP1 may also be spaced apart from each other in the second direction D2. Next, an etching process may be performed using the first mask pattern MP1. The first sacrificial layer 117 and the channel layer CL may be partially removed by the etching process, and as a result, channel layer CL may be divided into a plurality of patterns, which are spaced apart from each other in the second direction D2.

Referring to FIGS. 8A, 8B, and FIG. 8C, the first sacrificial layer 117, The first mask pattern MP1 of FIG. 7B and the channel layer CL of FIG. 7B may be planarized to expose a top surface of the mold insulating pattern 115, and the channel patterns CP may be formed from the channel layer CL of FIG. 7B. The first sacrificial layer 117 of FIG. 7B may be removed, after the formation of the channel patterns CP. In an embodiment, the first sacrificial layer 117 may be removed by an etching process having an etch selectivity with respect to the mold insulating patterns 115 and the channel patterns CP. As a result, the channel patterns CP may be exposed to the outside.

A conductive layer BL2L may be formed on the channel pattern CP, the first bit line BL1, and the mold insulating pattern 115. The conductive layer BL2L may be formed to have a uniform thickness. The conductive layer BL2L may be patterned to form a plurality of patterns, which are spaced apart from each other in the second direction D2. The patterns of the conductive layer BL2L may extend in the first direction D1, when viewed in a plan view. In an embodiment, the conductive layer BL2L may be formed using an atomic layer deposition (ALD) method. Alternatively, the conductive layer BL2L may be formed using at least one of physical vapor deposition (PVD), thermal chemical vapor deposition (thermal CVD), low-pressure chemical vapor deposition (LP-CVD), and plasma enhanced chemical vapor deposition (PE-CVD) methods. The conductive layer BL2L may be formed of or include the same or similar material as the second bit line BL2. For example, the conductive layer BL2L may be formed of or include doped polysilicon, metallic materials, conductive metal nitride materials, conductive metal silicide materials, conductive metal oxide materials, or combinations thereof.

A second sacrificial layer 119 may be formed on the conductive layer BL2L to cover the conductive layer BL2L and the mold insulating pattern 115. The second sacrificial layer 119 may have a substantially flat top surface. The second sacrificial layer 119 may include an insulating material. For example, the second sacrificial layer 119 may include a spin-on-hardmask (SOH) material.

Referring to FIG. 9, the second sacrificial layer 119 and the conductive layer BL2L may be removed to expose the top surface of the mold insulating pattern 115. A top surface of the conductive layer BL2L, a top surface of the second sacrificial layer 119, and a top surface of the mold insulating pattern 115 may be coplanar with each other, and the top surface of the conductive layer BL2L may be exposed to the outside. The conductive layer BL2L may form a plurality of patterns, which are spaced apart from each other in the first direction D1. In an embodiment, the removal of the second sacrificial layer 119 and the conductive layer BL2L may be performed through a chemical mechanical polishing (CMP) process.

Referring to FIG. 10, portions of the conductive layer BL2L may be removed through an etching process. For example, the portions of the conductive layer BL2L, which is in contact with the channel pattern CP, may be removed through an etch-back process to expose a side surface of the channel pattern CP and a side surface of the second sacrificial layer 119. As a result of the etching process, the second bit line BL2 may be formed. Next, the second sacrificial layer 119 may be further removed. For example, an ashing process and a strip process may be performed to remove the second sacrificial layer 119.

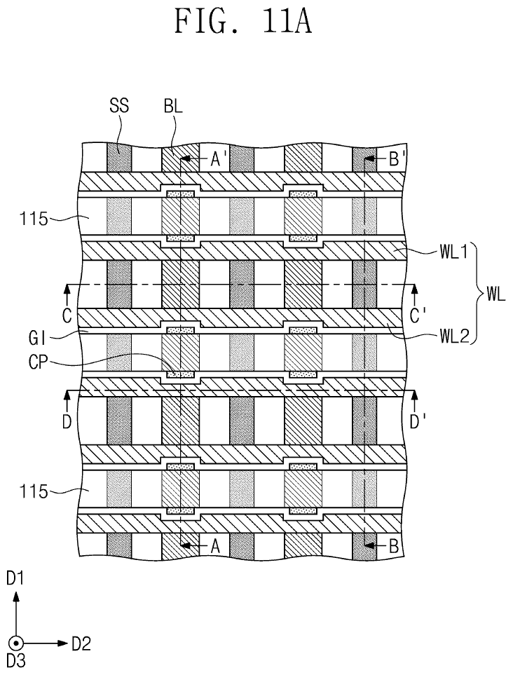

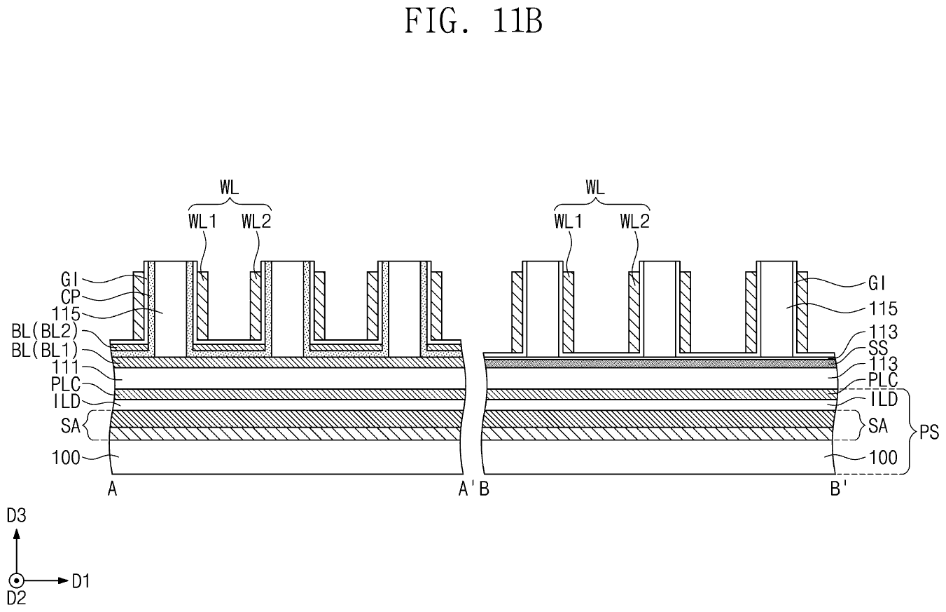

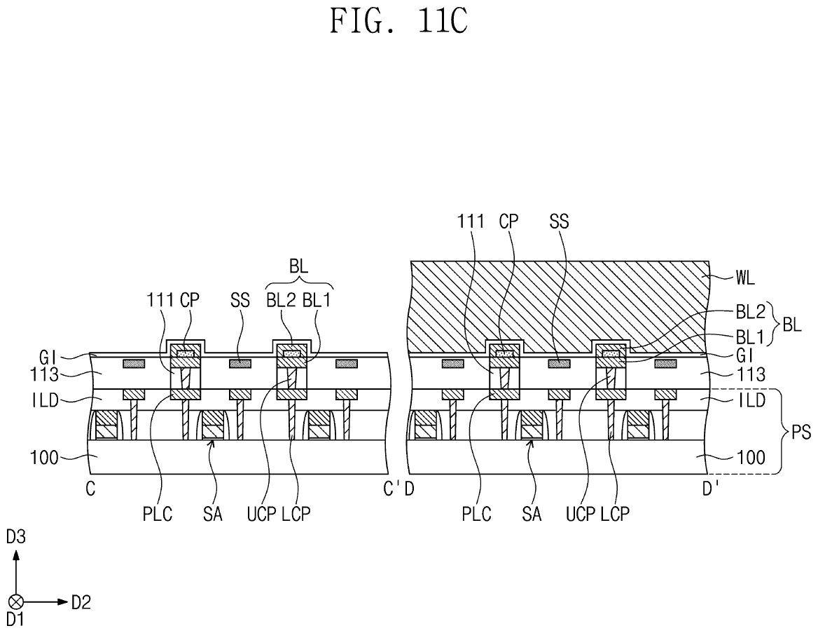

Referring to FIGS. 11A, 11B, and 11C, the gate insulating layer GI and a preliminary gate conductive layer may be sequentially formed on the second bit lines BL2. The gate insulating layer GI may cover the second bit lines BL2, the channel patterns CP and the mold insulating patterns 115 with a uniform thickness. The preliminary gate conductive layer may cover the gate insulating layer GI with a uniform thickness. The gate insulating layer GI and the preliminary gate conductive layer may be formed using at least one of physical vapor deposition (PVD), thermal chemical vapor deposition (thermal CVD), low-pressure chemical vapor deposition (LP-CVD), plasma enhanced chemical vapor deposition (PE-CVD), or atomic layer deposition (ALD) technologies. Next, an anisotropic etching process may be performed on the preliminary gate conductive layer to form the first and second word lines WL1 and WL2. The anisotropic etching process may be performed such that top surfaces of the first and second word lines WL1 and WL2 are lower than top surfaces of the channel patterns CP.

Although not illustrated in the drawings, according to an embodiment of the inventive concept, a spacer layer (not shown) may be formed on the preliminary gate conductive layer, after the formation of the preliminary gate conductive layer.

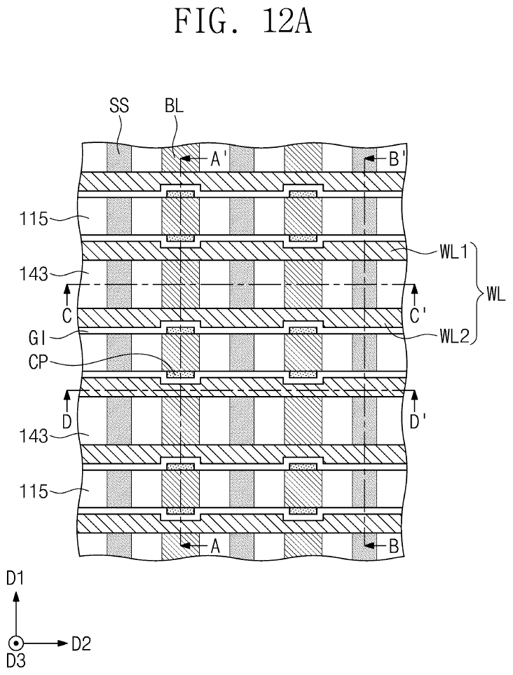

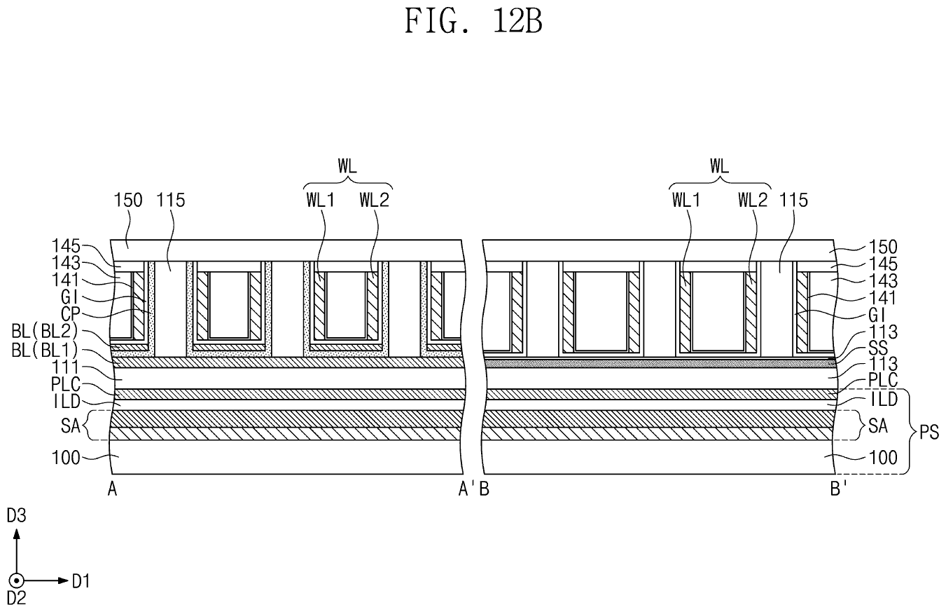

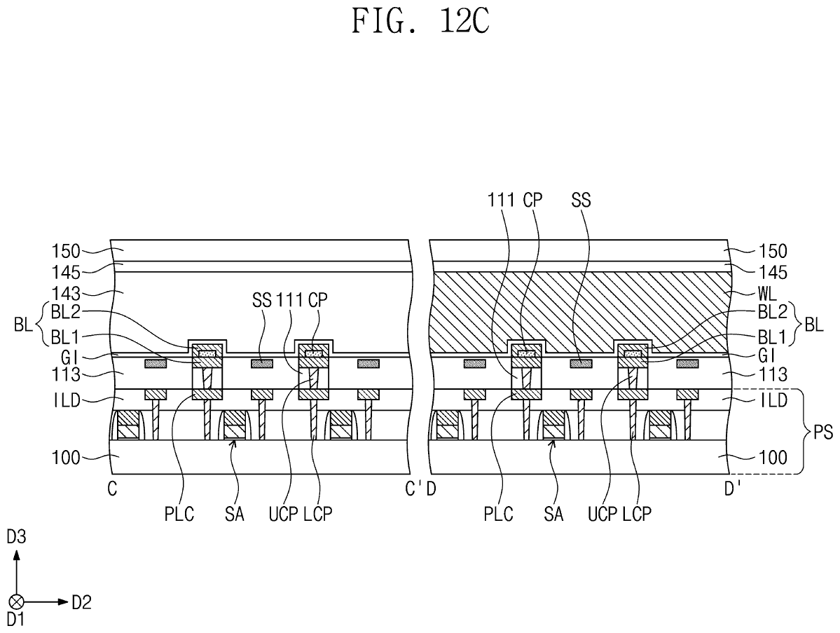

Referring to FIGS. 12A, 12B, and 12C, after the formation of the first and second word lines WL1 and WL2, a first capping layer of a uniform thickness may be formed on the semiconductor substrate 100. Next, a first insulating layer and a second capping layer may be sequentially formed to fill the trench, in which the first capping layer is formed. In an embodiment, the first and second capping layers may be formed of or include at least one of silicon nitride (SiN), silicon oxynitride (SiON), silicon carbide (SiC), silicon carbon nitride (SiCN), and combinations thereof.

A planarization process may be performed on the first capping layer, the first insulating layer, and the second capping layer to expose a top surface of the mold insulating pattern 115. Accordingly, the first capping pattern 141, the first insulating pattern 143, and the second capping pattern 145 may be formed. A second insulating layer may be formed on the second capping pattern 145 and the mold insulating pattern 115.

Referring to FIGS. 3A, 3B, and 3C, the second insulating layer may be patterned to form a second insulating pattern 150, and during this, the channel patterns CP may be partially etched. The landing pads LP may be in contact with upper portions of corresponding ones of the channel patterns CP and may fill empty spaces, which are formed by removing upper portions of the second insulating pattern 150. Thereafter, the data storage patterns DSP may be formed to be connected to the landing pads LP, respectively.

According to an embodiment of the inventive concept, a second bit line, which is connected to a first bit line, may be disposed on a channel pattern. During a fabrication process, the second bit line may be less oxidized than the first bit line, and thus, an electrical conductivity of the second bit line may be higher than that of the first bit line. This may improve the electrical characteristics of a semiconductor memory device.

According to an embodiment of the inventive concept, the second bit line and a gate insulating pattern may be provided between a word line and a horizontal channel portion of the channel pattern to increase a distance between the word line and the channel pattern. Thus, it may be possible to reduce a strength of an electric field produced between the word line and the channel pattern and to reduce or prevent or suppress charge traps from migrating or being moved from the horizontal channel portion to a vertical channel portion of the channel pattern.

It will be understood that spatially relative terms such as ‘top,’ ‘above,’ ‘upper,’ ‘upper portion,’ ‘upper surface,’ ‘bottom,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor memory device, comprising:
a first bit line that extends in a first direction;
a word line that extends in a second direction intersecting the first direction;
a channel pattern between the first bit line and the word line, the channel pattern comprising a horizontal channel portion, which is electrically connected to the first bit line, and a vertical channel portion, which extends from the horizontal channel portion in a third direction perpendicular to the first and second directions; and
a second bit line, which is electrically connected to the first bit line and is in contact with a top surface and at least a portion of a side surface of the horizontal channel portion.

2. The semiconductor memory device of claim 1, wherein each of the first and second bit lines comprises at least one of metallic materials, conductive metal nitride materials, conductive metal silicide materials, or conductive metal oxide materials.

3. The semiconductor memory device of claim 2, wherein a first portion of the first bit line, which is in contact with the horizontal channel portion, comprises a conductive metal oxide material, and
an electrical conductivity of the first portion is lower than an electrical conductivity of the second bit line.

4. The semiconductor memory device of claim 1, wherein the first bit line is in contact with a bottom surface of the horizontal channel portion, and wherein the second bit line is in contact with the top surface, the side surface, and an opposing side surface of the horizontal channel portion, and is in contact with a top surface of the first bit line.

5. The semiconductor memory device of claim 1, wherein the second bit line comprises a plurality of second bit lines, which are spaced apart from each other in the first direction.

6. The semiconductor memory device of claim 1, wherein a width of the first bit line in the second direction is greater than a width of the horizontal channel portion in the second direction.

7. The semiconductor memory device of claim 1, wherein the second bit line is in contact with a side surface of the vertical channel portion.

8. The semiconductor memory device of claim 1, further comprising a gate insulating pattern between the word line and the channel pattern,
wherein the gate insulating pattern extends on a top surface of the second bit line such that the gate insulating pattern and the second bit line are stacked between the word line and the horizontal channel portion.

9. The semiconductor memory device of claim 1, wherein the channel pattern comprises an oxide semiconductor material.

10. The semiconductor memory device of claim 9, wherein the channel pattern has a multi-layered structure of the oxide semiconductor material.

11. The semiconductor memory device of claim 1, further comprising:
a landing pad electrically connected to the vertical channel portion of the channel pattern; and
a data storage pattern on the landing pad.

12. A semiconductor memory device, comprising:
a bit line that extends in a first direction;
a word line that extends in a second direction intersecting the first direction; and
a channel pattern between the bit line and the word line, the channel pattern comprising a horizontal channel portion electrically connected to the bit line and a vertical channel portion, which protrudes from the horizontal channel portion in a third direction perpendicular to the first and second directions,
wherein the bit line comprises:
a first bit line on the channel pattern opposite the word line and in contact with a bottom surface of the horizontal channel portion; and
a second bit line electrically connected to the first bit line and between the word line and the horizontal channel portion.

13. The semiconductor memory device of claim 12, wherein the bit line comprises at least one of metallic materials, conductive metal nitride materials, conductive metal silicide materials, or conductive metal oxide materials.

14. The semiconductor memory device of claim 12, wherein a first portion of the first bit line, which is in contact with the horizontal channel portion, comprises a conductive metal oxide material, and
an electrical conductivity of the first portion is lower than an electrical conductivity of the second bit line.

15. The semiconductor memory device of claim 12, wherein a width of the first bit line in the second direction is greater than a width of the horizontal channel portion in the second direction.

16. The semiconductor memory device of claim 12, wherein the second bit line is in contact with top and side surfaces of the horizontal channel portion.

17. The semiconductor memory device of claim 12, wherein the channel pattern comprises an oxide semiconductor material.

18. The semiconductor memory device of claim 12, further comprising a gate insulating pattern between the word line and the channel pattern,
wherein the gate insulating pattern extends on a top surface of the second bit line such that the gate insulating pattern and the second bit line are stacked between the word line and the horizontal channel portion.

19. A semiconductor memory device, comprising:
a peripheral circuit structure including peripheral circuits on a semiconductor substrate and a lower insulating layer on the peripheral circuits;
first bit lines on the peripheral circuit structure and extending in a first direction;
mold insulating patterns extending in a second direction to cross the first bit lines;
word lines between the mold insulating patterns and extending in the second direction to cross the first bit lines;
channel patterns between the first bit lines and the word lines, each of the channel patterns comprising a horizontal channel portion, which is connected to the first bit line, and first and second vertical channel portions, which extend from opposite end portions of the horizontal channel portion in a third direction perpendicular to the first and second directions;
second bit lines electrically connected to the first bit lines, the second bit lines being between the word lines and the horizontal channel portion of the channel patterns;
a gate insulating pattern between the channel patterns and the word lines and between the second bit line and the word lines;
landing pads electrically connected to the first and second vertical channel portions of the channel patterns, respectively; and
data storage patterns on the landing pads, respectively.

20. The semiconductor memory device of claim 19, wherein each of the second bit lines is in contact with top and side surfaces of the horizontal channel portion and side surfaces of the first and second vertical channel portions of each of the channel patterns, respectively.
